(19) United States
(12) Patent Application Publication
(10) Pub. No.: US 2006/0022248 A1
(43) Pub. Date: Feb. 2, 2006

(54) Electronic data memory device for a high read current

(76) Inventors: Bjorn Fischer, Munchen (DE); Franz Hofmann, Munchen (DE); Richard Johannes Luyken, Munchen (DE); Andreas Spitzer, Ottobrunn (DE)

Correspondence Address: JENKINS, WILSON & TAYLOR, P. A., 3100 TOWER BLVD, SUITE 1400, DURHAM, NC, 27707, US

(21) Appl. No.: 11/167,386

(22) Filed: Jun. 27, 2005

(30) Foreign Application Priority Data
Jul. 28, 2004 (DE) 102004036461.3

(51) Int. Cl. H01L 27/108

(52) U.S. Cl. 257/298

(57) ABSTRACT

Electronic data memory device for a high read current The invention provides a memory device arranged on a substrate (401) and having at least one memory cell (100) The memory cell comprises a storage capacitor (200) for storing an electrical charge and a selection transistor (300) for selecting the memory cell (100). The selection transistor comprises a first conduction electrode (301), a second conduction electrode (302) and a control electrode (303) , the control electrode (303) being provided by a gate unit (400) having a fin (405) projecting from the substrate (401), which fin is surrounded by a gate oxide layer (406) and a gate electrode layer (403) in such a way that first and second gate elements (408a, 408b) are provided at opposite lateral areas of the fin (405), a third gate element (408c) being provided at an area of the fin (405) that is parallel to the surface of the substrate (401).

Electronic data memory device for a high read current The present invention generally relates to memory devices for data storage which are arranged such that they are miniaturized and integrated on a substrate. In particular, the present invention relates to a DRAM memory cell (DRAM=Dynamic Random Access Memory) having a storage capacitor and a selection transistor connected to the storage capacitor. A data storage is carried out in the form of a charge of the storage capacitor, memory states “0” and “1” corresponding to a positively and negatively charged storage capacitor.

The storage capacitor is written to or read by means of an addressing of the selection transistor. The charge stored in the storage capacitor recombines on account of leakage currents through the selection transistor, inter alia, in such a way that the charge must be refreshed in a predetermined refresh cycle. The refresh cycle is typically 64 milliseconds (ms).

The present invention specifically relates to an electronic memory device for data storage, which is arranged on a substrate, having at least one memory cell arranged in a memory cell array, the at least one memory cell comprising a storage capacitor for storing an electrical charge, which has a first capacitor electrode, a second capacitor electrode, which is electrically insulated from the first capacitor electrode and is electrically connected to the substrate, and a dielectric layer introduced between the first and second capacitor electrode and a selection transistor for selecting the at least one memory cell, the selection transistor having a first conduction electrode, which is connected to a bit line of the memory cell array, a second conduction electrode, which is connected to the first capacitor electrode, and a control electrode, which is connected to a word line of the memory cell array.

In this case, the control electrode is provided by a gate unit having a fin projecting from the substrate, which fin is surrounded by a gate oxide layer and a gate electrode layer in such a way that first and second gate elements are formed at opposite lateral areas of the fin, a third gate element being provided at an area of the fin or of the ridge that is parallel to the surface of the substrate.

The miniaturization of memory cells each having a selection transistor and a storage capacitor that accompanies an increasing integration density entails problems with regard to the current driver capability and the leakage current behavior of the selection transistor. A high current driver capability of the selection transistor is necessary in order to be able to charge the storage capacitor sufficiently rapidly.

On the other hand, it is necessary to provide low leakage currents in the selection transistor in order to increase a data retention time, or in order to design the refresh cycle to be as large as possible. In the case of selection transistors for DRAM memory devices, the current driver capability generally decreases with advancing miniaturization since, by way of example, a gate oxide layer thickness and doping profiles cannot be downscaled correspondingly.

In order to increase a current driver capability, it has been proposed to provide so-called double gate transistors instead of planar selection transistors, said double gate transistors having a higher current intensity relative to the “pitch” area. In the case of a three-dimensional design, a so-called fin (or a ridge) is provided, which forms the basis for a three-dimensional gate unit. In the case of a fin field effect transistor of this type, the current intensity can be increased by a multiple in comparison with a conventional planar selection transistor given the same basic area.

However, the fabrication of fin field effect transistors has hitherto been restricted to an SOI (Silicon On Insulator) material. The use of such an SOI material is problematic, however, for DRAM memory cells or the fabrication of memory cells assigned thereto since an SOI wafer causes additional costs. Secondly, so-called “floating body” effects cannot be avoided

In one further development, it has been proposed in the prior art to provide a fin field effect transistor with a so-called “bulk fin”. A gate unit based on a conventional bulk fin of this type is shown schematically in FIG. 5. A silicon wafer Si has a fin F projecting from the latter perpendicular to its surface.

The silicon wafer is coated with an insulation layer, which is formed for example from a silicon dioxide material (SiO₂). In this case, a layer having a small layer thickness surrounds the fin F as a gate oxide GOX. A conductive layer on the gate oxide layer GOX and the insulation layer SiO₂ is formed for example from a polysilicon material (Poly-Si).

As illustrated in FIG. 5, the conventional fin field effect transistor thus has two gate elements G1 and G2. Although the conventional design of the gate element of a fin field effect transistor ensures a fabrication of the fin on a bulk silicon of a DRAM memory device with a high current driver capability per area, a fabrication of a structure of this type is associated with considerable process-technological problems, however. Thus, a typical gate length is 50 nanometers (nm), a gate height is 200 nanometers and a fin width is 20 nanometers. Since the current intensity that can be achieved when reading or writing to the storage capacitor is determined by the height of the fin of the fin field effect transistor, designed as a selection transistor, a channel layer length (corresponds to the fin height) amounts to at least 2.5 times the channel layer width (corresponds to the fin width) in the case of the conventional arrangement. The fin width corresponding to the channel layer width thus has to be patterned very finely in terms of process technology and makes extreme requirements of the lithography since it is usually necessary to provide a sublithographic feature size for the fin.

DE 103 20 293.0 discloses a DRAM memory cell and a method for fabricating a DRAM memory cell of this type, the selection transistor (cell transistor) of the memory cell being designed as a fin-FET with a bulk fin. The memory device disclosed in DE 103 20 2 39.0 has a double gate field effect transistor in such a way that the channel layer length of the latter amounts to at least 2.5 times the channel layer width. Such a design of the channel layer width (fin width) in relation to the channel layer length (fin depth) disadvantageously makes stringent requirements of the lithography in such a way that sublithographic feature sizes have to be achieved. This causes high fabrication costs in the fabrication of the double gate field effect transistor of the memory cell.

An essential disadvantage of the known memory devices using a fin field effect transistor is that the production of the fin can be carried out with a high process-technological outlay. This is disadvantageously associated with an increase in costs in the fabrication of the entire memory device. It is difficult, moreover, to fabricate such small structures with small manufacturing fluctuations.

Consequently, it is an object of the present invention to provide a memory cell for a memory device, the memory cell comprising a selection transistor having a high current driver capability in conjunction with a low leakage current, it being possible to fabricate a fin of the fin transistor that forms the gate element with a low outlay together with low process costs.

This object is achieved according to the invention by means of an electronic memory device for data storage having the features of Patent claim 1.

Further refinements of the invention emerge from the subclaims.

An essential concept of the invention consists in designing a gate element of a field effect transistor, serving as a selection transistor for a memory cell, in such a way that, besides the gate elements formed at the lateral side areas of the fin, a third gate element is provided at the area (upper area) of the gate element that is parallel to the substrate area. In this way, it is possible to reduce the fin height of the fin field effect transistor given the same current driver capability, thereby achieving considerable advantages in terms of process technology.

A trigate field effect transistor is thus advantageously formed, which has all the advantages of a bulk fin field effect transistor in conjunction with an increased current driver capability. The process-technologically relevant requirements made of the fin width can be considerably reduced compared with the conventional dual gate fin field effect transistor.

The heart of the invention consists in designing the geometry of the gate element such that the upper gate controls the region in the center of the fin, which region is controlled only to a limited extent by the two lateral gates, in such a way that no undesirable leakage paths, etc. occur.

The electronic memory device for data storage according to the invention is arranged on a substrate and has at least one memory cell arranged in a memory cell array, the at least one memory cell essentially comprising:

a) a storage capacitor for storing an electrical charge, which has:

a1) a first capacitor electrode;

a2) a second capacitor electrode, which is electrically insulated from the first capacitor electrode and is electrically connected to the substrate; and

a3) a dielectric layer introduced between the first capacitor electrode and the second capacitor electrode; and

b) a selection transistor for selecting the at least one memory cell, which has:

b1) a first conduction electrode, which is connected to a bit line of the memory cell array;

b2) a second conduction electrode, which is connected to the first capacitor electrode; and

b3) a control electrode, which is connected to a word line of the memory cell array,

c) the control electrode being provided by a gate unit having a fin projecting from the substrate, which fin is surrounded by a gate oxide layer and a gate electrode layer in such a way that first and second gate elements are formed at opposite lateral areas of the fin,

d) a third gate element being provided at an area of the fin that is parallel to the surface of the substrate.

Advantageous developments and improvements of the respective subject matter of the invention are found in the subclaims.

In accordance with one preferred development of the present invention, the third gate element is provided in the center of the area of the fin that is parallel to the surface of the substrate.

In accordance with a further preferred development of the present invention, the memory cell is designed as a DRAM memory cell.

In accordance with yet another preferred development of the present invention, the dielectric layer has a high dielectric constant.

In accordance with yet another preferred development of the present invention, the selection transistor is designed as a normally off n-channel field effect transistor. In this case, the substrate is preferably provided as a p-conducting semiconductor substrate.

In accordance with yet another preferred development of the present invention, a gate length amounts to 1.5 times a fin width.

In accordance with yet another preferred development of the present invention, a gate length reaches down over the source/drain junctions.

It is advantageous if the fin depth corresponds at least to the fin width.

The memory cells are expediently arranged in matrix-type fashion in the memory cell array.

In accordance with yet another preferred development of the present invention, the fin is formed such that it essentially projects in ridge-type fashion from the substrate.

In accordance with yet another preferred development of the present invention, the fin or the channel layer has an essentially homogeneous doping over the profile of the fin depth or the channel layer length. It is expedient for the fin or the channel layer to have a doping atom concentration of at most 10¹⁷ cm⁻³.

In accordance with yet another preferred development of the present invention, the storage capacitor for storing an electrical charge is designed as a trench capacitor (DT, deep trench).

In accordance with yet another preferred development of the present invention, the storage capacitor for storing an electrical charge is designed as a stacked capacitor.

The memory device according to the invention thus comprises memory cells having selection transistors distinguished by a high current driver capability. At the same time, the requirements made of a process technology are reduced since a height of the fin is reduced in comparison with a fin width.

Exemplary embodiments of the invention are illustrated in the drawings and are explained in more detail in the description below.

### IN THE DRAWINGS

FIG. 1 shows a schematic circuit diagram of a memory cell having a storage capacitor and a selection transistor arranged together;

FIG. 2 shows a cross section through a gate unit on which a fabrication of a fin field effect transistor serves as a selection transistor for a memory cell according to the invention, in accordance with a preferred exemplary embodiment of the present invention;

FIG. 3 shows a current-voltage characteristic of a fin field effect transistor according to the invention;

FIG. 4 shows the current-voltage characteristic of a fin field effect transistor according to the invention as shown in FIG. 3 in greater detail; and

FIG. 5 shows a cross section through a gate unit of a conventional fin field effect transistor.

In the figures, identical reference symbols designate identical or functionally identical components or steps.

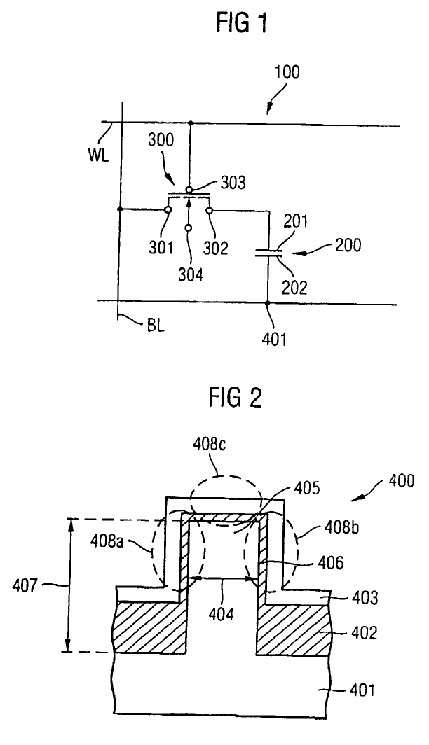

FIG. 1 shows a schematic circuit diagram of a memory cell having a selection transistor according to the invention.

As shown in FIG. 1, dynamic memory cells are composed of a selection transistor and a storage capacitor. The memory states 0 and 1 correspond to the positively and negatively charged storage capacitor. Owing to recombination or leakage currents, the charge stored in the storage capacitor must be refreshed at regular intervals. Such a refresh cycle is typically 64 milliseconds (ms).

FIG. 1 shows a selection transistor as a normally off n-channel field effect transistor (FET) having a first conduction electrode 301 (first source/drain electrode) and a second conduction electrode 302 (second source/ drain electrode) . The first conduction electrode of the selection transistor 300 is connected to a bit line BL, while the second conduction electrode 302 of the selection transistor 300 is connected to a first terminal of the storage capacitor 200. The second terminal of the storage capacitor 200 is connected to a substrate terminal 401.

Furthermore, the selection transistor 300 has a control electrode 303 connected to a word line WL of the memory device. Consequently, the selection transistor 300 can be addressed via its control electrode 303 by means of the word line WL of the memory device, whereupon the storage capacitor 200 is connected to the bit line BL of the memory device.

It should be pointed out that the storage capacitor 200 is formed in integrated fashion together with the selection transistor 300 and may be provided as a so-called trench capacitor or as a so-called stacked capacitor. Such a three-dimensional design of the storage capacitor makes it possible to further miniaturize a memory cell of a memory cell array forming the memory device.

FIG. 2 shows a cross section for a gate unit 400 provided as a basis for a fin field effect transistor in accordance with a preferred exemplary embodiment of the present invention. According to the invention, a fin 405 is formed in projecting fashion on a substrate 401, a fin width being identified by a reference symbol 404 and a fin depth (fin height) being identified by a reference symbol 407. It should be pointed out that a channel layer length of the fin field effect transistor is defined by the fin depth 407, while a channel layer width of the fin field effect transistor is defined by the fin width 404.

An insulation layer 402, which is preferably formed from a silicon dioxide material (SiO₂), is deposited on the substrate 401. The insulation layer 402 merges with a thin gate oxide layer 406 in the region of the fin. In accordance with the preferred exemplary embodiment of the present invention, the fin 405 of the fin field effect transistor (fin-FET) is formed in such a way that the fin depth 407 amounts to no more than 1.5 times the fin width 404.

Three different gate elements 408a, 408b and 408c are provided as a result of the construction illustrated in FIG. 2. The gate elements 408a and 408b are arranged laterally at opposite areas of the fin 405 as is provided in the case of a conventional double gate fin field effect transistor according to the prior art and is disclosed in the publication DE 103 20 239.9, which is incorporated herein by reference.

According to the invention, as a result of the construction of the fin 405 as shown in FIG. 2, a third gate element 408c is provided at an area of the fin 405 that is parallel to the surface of the substrate 401. The third gate element 408c is preferably provided in the center of the area of the fin 405 that is parallel to the surface of the substrate 401.

As a result of the third gate, a so-called trigate fin field effect transistor is formed, which makes it possible, with a reduced leakage current, to provide a high current driver capability when reading or writing to the storage capacitor connected to the selection transistor. In the fabrication of a trigate fin field effect transistor of this type, there is the advantage that a fin width 404 is increased in comparison with the conventional double gate fin field effect transistor. Critical sublithographic dimensions are thus avoided, as a result of which the fabrication costs for the memory cell are lowered overall. This advantageously reduces requirements made of the lithography of the memory cell relating to the selection transistor.

The upper gate element 408c (FIG. 2) lies in the region of the center of the fin in such a way that no undesirable leakage paths, etc. can occur. A typical dimensioning of a trigate fin field effect transistor is as follows:

(i) Gate length=L;

(ii) Fin width=(⅔)*L;

(iii) Depth of the source/drain junctions=L/2; and

(iv) Gate depth=(L/2)+20 nm.

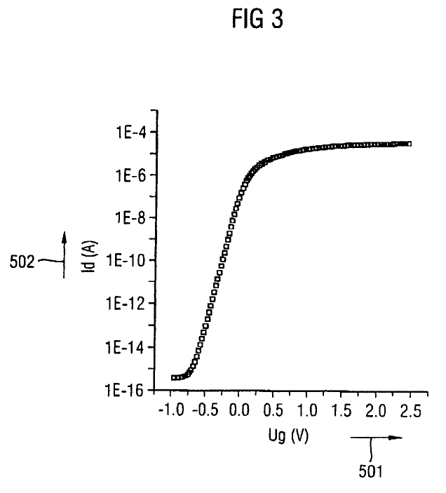

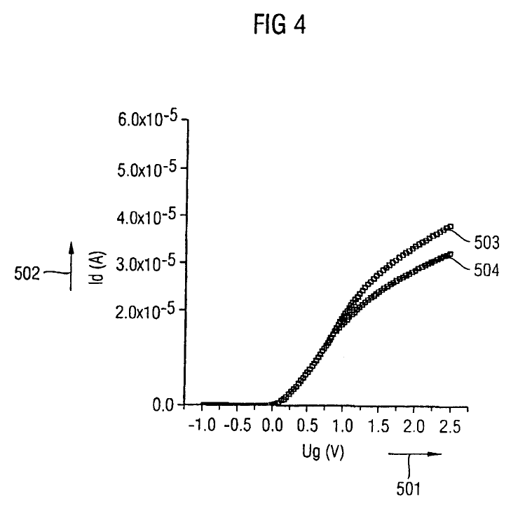

FIGS. 3 and 4 in each case show current-voltage characteristics of the trigate fin field effect transistor according to the invention. It should be pointed out that the profiles shown in FIGS. 3 and 4 are based on a simulation with the following data:

Gate length=L=60 nm, fin width=40 nm, depth of the source/drain junction=30 nm, gate depth along the fin=50 nm, a homogeneous subdoping of 3×10¹⁷ cm⁻³ being provided.

FIG. 3 shows an overview of a current-voltage profile with a logarithmic representation of the source/drain current 502, whereas FIG. 4 illustrates a detail view with a linear representation of the source/drain current profile 502. The source/drain current 502 (Id(A)) is in each case represented as a function of a gate voltage 501 (Ug(V)). Two different profiles for fin field effect transistors having a different channel width are plotted in each case in the diagrams of FIGS. 3 and 4.

The two profiles can be distinguished in the detail view in FIG. 4, a first current profile 504 being assigned to the trigate fin field effect transistor according to the invention with a width of 40 nanometers (nm), while the second current profile 504 corresponds to a fin field effect transistor with a reduced fin width of 20 nanometers (nm).

The comparison—shown in FIG. 3—between the first current profile 503 for a fin field effect transistor component having a wider fin and a second current profile 504 for a fin field effect transistor component having a narrower fin (fin width 20 nm) shows that the switching behavior has identical properties in both cases.

The design of a fin field effect transistor according to the invention thus ensures that, on account of the formation of a third gate element 408c besides the first and second gate elements 408a, 408b (lateral gate elements), a high current driver capability in conjunction with a reduced leakage current is obtained.

In this way, it is possible to provide fin field effect transistors as selection transistors for memory cells in which a large aspect ratio is avoided. The process-technological fabrication steps are thereby simplified, as a result of which fabrication costs are saved.

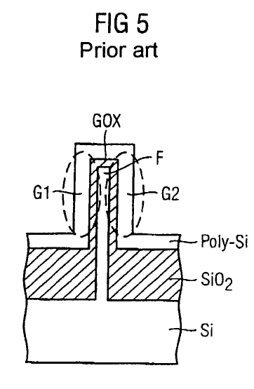

With regard to the conventional arrangement of a fin field effect transistor having only two lateral gate elements as illustrated in FIG. 5, reference shall be made to the introduction to the description.

Although the present invention has been described above on the basis of preferred exemplary embodiments, it is not restricted thereto, but rather can be modified in diverse ways.

Moreover, the invention is not restricted to the application possibilities mentioned.

List of Reference Symbols

In the figures, identical reference symbols designate identical or functionally identical components or steps.
100 Memory cell
200 Storage capacitor
201 First capacitor electrode
202 Second capacitor electrode
203 Dielectric layer
300 Selection transistor
301 First conduction electrode
302 Second conduction electrode
303 Control electrode
304 Substrate terminal
400 Gate unit
401 Substrate
402 Insulation layer
403 Gate electrode layer
404 Fin width
405 Fin
406 Gate oxide layer
407 Fin depth
408a First gate element
408b Second gate element
408c Third gate element
501 Gate voltage
502 Source-drain current
503 First current profile
504 Second current profile

1. Electronic memory device for data storage, which is arranged on a substrate, having at least one memory cell arranged in a memory cell array, the at least one memory cell having:
a) a storage capacitor for storing an electrical charge, which has:
a1) a first capacitor electrode;
a2) a second capacitor electrode, which is electrically insulated from the first capacitor electrode and is electrically connected to the substrate; and
a3) a dielectric layer introduced between the first capacitor electrode and the second capacitor electrode; and
b) a selection transistor for selecting the at least one memory cell, which has:
b1) a first conduction electrode, which is connected to a bit line of the memory cell array;
b2) a second conduction electrode, which is connected to the first capacitor electrode; and
b3) a control electrode, which is connected to a word line of the memory cell array,
c) the control electrode being provided by a gate unit having a fin projecting from the substrate, which fin is surrounded by a gate oxide layer and a gate electrode layer in such a way that first and second gate elements are formed at opposite lateral areas of the fin, wherein
d) a third gate element is provided at an area of the fin that is parallel to the surface of the substrate.

2. Device according to claim 1, wherein the third gate element is provided in the center of the area of the fin that is parallel to the surface of the substrate.

3. Device according to claim 1, wherein the memory cell is designed as a DRAM memory cell.

4. Device according to claim 1, wherein the dielectric layer has a high dielectric constant.

5. Device according to claim 1, wherein the selection transistor is designed as a normally off n-channel field effect transistor.

6. Device according to claim 1 wherein the substrate is designed as a p-conducting semiconductor substrate.

7. Device according to claim 1, wherein a gate length amounts to 1.5 times a fin width.

8. Device according to claim 1, wherein the gate depth reaches down over the depth of the source/drain junction.

9. Device according to claim 1, wherein the memory cells are arranged in matrix-type fashion in the memory cell array.

10. Device according to claim 1, wherein the fin is formed such that it essentially projects in ridge-type fashion from the substrate.

11. Device according to claim 1, wherein the fin has an essentially homogeneous doping over the profile of the fin depth.

12. Device according to claim 1, wherein the fin has a doping atom concentration of at most 1*10¹⁷ cm⁻³.

13. Device according to claim 1, wherein the storage capacitor for storing an electrical charge is designed as a trench capacitor.

14. Device according to claim 1, wherein the storage capacitor for storing an electrical charge is designed as a stacked capacitor.
